(19) United States
(12) Patent Application Publication
(10) Pub. No.: US 2024/0314928 A1
(43) Pub. Date: Sep. 19, 2024

(54) Ultra-Thin Sandwich Component

(71) Applicant: KYOCERA AVX Components Corporation, Fountain Inn, SC (US)

(72) Inventors: Cory Nelson, Simpsonville, SC (US); Ronald Demcko, Raleigh, NC (US); Jeff Borgman, Myrtle Beach, SC (US)

(21) Appl. No.: 18/581,441

(22) Filed: Feb. 20, 2024

Related U.S. Application Data
(60) Provisional application No. 63/490,781, filed on Mar. 17, 2023.

(51) Int. Cl. H05K 1/11; H01P 1/20; H05K 1/02; H05K 1/18; H05K 3/00; H05K 3/40

(52) U.S. Cl. CPC H05K 1/111; H01P 1/20; H05K 1/0237; H05K 1/181; H05K 3/0047; H05K 3/0064; H05K 3/0067; H05K 3/403; H05K 2201/09181; H05K 2201/09981; H05K 2201/1006; H05K 2203/025; H05K 2203/1461

(57) ABSTRACT

Components, methods of forming components, and methods of assembling components on an electronic device are provided. For example, a method of forming a component includes providing a first substrate having a first surface, a second surface opposite the first surface along a height direction, and an initial thickness from the first surface to the second surface along the height direction; forming one or more vias in the first substrate, each via extending from the first surface to the second surface of the first substrate; depositing one or more conductive pathways on the first surface of the first substrate; plating the one or more vias; disposing a second substrate on the first surface of the first substrate to form a component sandwich; processing the second surface of the first substrate to reduce a thickness of the component sandwich; and forming one or more contact pads on the first substrate.

### RELATED APPLICATION

The present application is based upon and claims priority to U.S. Provisional Patent Application Ser. No. 63/490,781, having a filing date of Mar. 17, 2023, which is incorporated herein by reference.

### BACKGROUND

High frequency radio signal communication has increased in popularity. For example, the demand for increased data transmission speed for wireless smartphone connectivity has driven demand for high frequency components, including those configured to operate at 5G spectrum frequencies. A trend towards miniaturization has also increased the desirability of small, passive components for handling such high frequency signals. However, miniaturization increases the difficulty of surface mounting small, passive components suitable for operation in the 5G frequency spectrum. A component that can be reduced in height without adversely affecting component performance would be welcomed in the art.

### SUMMARY

In accordance with one embodiment of the present invention, a method of forming a component includes providing a first substrate having a first surface, a second surface opposite the first surface along a height direction, and an initial thickness from the first surface to the second surface along the height direction; forming one or more vias in the first substrate, each via of the one or more vias extending from the first surface of the first substrate to the second surface of the first substrate; depositing one or more conductive pathways on the first surface of the first substrate; plating the one or more vias; disposing a second substrate on the first surface of the first substrate to form a component sandwich; processing the second surface of the first substrate to reduce a thickness of the component sandwich and define a processed second surface of the first substrate; and forming one or more contact pads on the processed second surface of the first substrate.

In accordance with another embodiment of the present invention, a method of forming a component includes providing a first substrate having a first surface, a second surface opposite the first surface along a height direction, and an initial thickness from the first surface to the second surface along the height direction; depositing one or more conductive pathways on the first surface of the first substrate, at least one conductive pathway of the one or more conductive pathways extending through the first substrate from the first surface to the second surface; disposing a second substrate on the first substrate, the second substrate having a first surface, a second surface opposite the first surface along a height direction, and an initial thickness from the first surface to the second surface along the height direction, the second surface of the second substrate positioned against the first surface of the first substrate; and processing the second surface of the first substrate to reduce the initial thickness of the first substrate to a processed thickness.

In accordance with still another embodiment of the present invention, a component includes a first substrate having a first surface and a second surface opposite the first surface; one or more vias defined in the first substrate, each via of the one or more vias extending from the first surface of the first substrate to the second surface of the first substrate, the one or more vias including a first via and a second via, the one or more vias including an electrically conductive material; one or more conductive pathways on the first surface of the first substrate, the one or more conductive pathways including a first conductive pathway extending from the first via to the second via; one or more contact pads formed on the second surface of the first substrate, each contact pad of the one or more contact pads surrounding a respective one via of the one or more vias at the second surface such that each contact pad is in electrical contact with a respective one via; and a second substrate having a first surface and a second surface opposite the first surface, the second substrate positioned over the first substrate such that the second surface of the second substrate is positioned in contact with the first surface of the first substrate. The component has a thickness of less than about 40 mils.

In accordance with yet another embodiment of the present invention, a method of assembling a component on an electronic device includes providing the component. The component includes a first substrate having a first surface and a second surface opposite the first surface; one or more vias defined in the first substrate, each via of the one or more vias extending from the first surface of the first substrate to the second surface of the first substrate, the one or more vias including a first via and a second via, the one or more vias plated with an electrically conductive material; one or more conductive pathways on the first surface of the first substrate, the one or more conductive pathways including a first conductive pathway extending from the first via to the second via; one or more contact pads formed on the second surface of the first substrate, each contact pad of the one or more contact pads surrounding a respective one via of the one or more vias at the second surface such that each contact pad is in electrical contact with a respective one via; and a second substrate having a first surface and a second surface opposite the first surface, the second substrate positioned over the first substrate such that the second surface of the second substrate is positioned in contact with the first surface of the first substrate. The component has a thickness of less than about 40 mil. The method also includes securing the component to the electronic device and processing the second substrate to reduce a thickness of the second substrate.

### BRIEF DESCRIPTION OF THE DRAWINGS

A full and enabling disclosure of the present invention, including the best mode thereof, directed to one of ordinary skill in the art, is set forth more particularly in the remainder of the specification, which makes reference to the appended figures in which:

FIG. 1 is a perspective view of a reduced height component assembled on an electronic device according to aspects of the present disclosure;

FIG. 2 is a flow chart illustrating a method of forming a component according to aspects of the present disclosure;

FIG. 3 is a perspective view of a first substrate of a component according to aspects of the present disclosure;

FIG. 4 is a perspective view of the first substrate of FIG. 3 having a plurality of vias defined therein according to aspects of the present disclosure;

FIG. 5 is a perspective view of the first substrate of FIG. 4 having two conductive pathways formed on a first surface thereof according to aspects of the present disclosure;

FIG. 6 is a perspective view of the first substrate of FIG. 5 having the conductive pathways extend through the plurality of vias according to aspects of the present disclosure;

FIG. 7 is a perspective view of the first substrate of FIG. 6 having a second substrate disposed thereon to form a component sandwich according to aspects of the present disclosure;

FIG. 8 is a perspective view of a second surface of the component sandwich of FIG. 7 according to aspects of the present disclosure;

FIG. 9 is a perspective view of a processed second surface of the component sandwich of FIG. 7 according to aspects of the present disclosure;

FIG. 10 is a perspective view of the processed surface of the component sandwich of FIG. 9 having a plurality of contact pads formed thereon according to aspects of the present disclosure; and

FIG. 11 is a flow chart illustrating a method of assembling a component on an electronic device according to aspects of the present disclosure.

Repeat use of reference characters in the present specification and drawing is intended to represent same or analogous features or elements of the invention.

### DETAILED DESCRIPTION

It is to be understood by one of ordinary skill in the art that the present discussion is a description of exemplary embodiments only and is not intended as limiting the broader aspects of the present invention, which broader aspects are embodied in the exemplary construction.

Generally speaking, the present invention is directed to reduced height components. For example, one or more conductive pathways may be sandwiched between two substrates, with a first substrate of the two substrates thinned or reduced in height before providing an outer surface of the sandwich component with one or more conductive areas to electrically connect the one or more conductive pathways to an electronic device (such as a printed circuit board or the like). A second substrate of the two substrates may be thinned or reduced in height to further reduce the height of the sandwich component. For instance, the sandwich component may be mounted on a mounting surface of the electronic device before the second substrate is processed to reduce the height of the sandwich component, or the second substrate may be processed to reduce the height of the sandwich component before the sandwich component is mounted on the mounting surface, embedded in the electronic device, or otherwise secured to the electronic device.

Processing one side of the component sandwich and then processing another side of the component sandwich, e.g., before or after mounting or securing the component sandwich to an electronic device, can allow at least one side of the component sandwich to be thinned more than previously allowed, e.g., to relatively extreme levels. Moreover, the other side of the component sandwich also may be thinned to further reduce the height or thickness of the component, e.g., such that the component may be fitted in an area or with other components that would not be possible for known or existing components of a larger height or thickness. As one example, after processing a first side of the component sandwich, the component sandwich may be singulated to create a chip, and when the chip is mounted in circuit, a second side opposite the first side is able to be thinned to a desired height. As another example, the second side may be thinned before securing the chip such that the chip may be embedded in the circuit substrate or the like.

Further, the change in the thickness of the initial substrate can also be used to change the RF performance of the component, such as the RF performance of one or more transmission lines deposited between the initial or first substrate and the second substrate of the component sandwich. For instance, a useful frequency range for a circuit including a thin component as described herein may be increased, e.g., the components as described herein may be used at higher frequencies that known components. Moreover, the conductive pathways or transmissions lines may be thinner than other components, e.g., the RF performance may be improved such that a width of a transmission line may be reduced, such as a reduction in transmission line width that corresponds to the reduction in component or chip size. As an example, thinner transmission lines can allow higher frequency filters, in smaller packages, which may improve passband loss and/or allow more poles in the same package to improve rejection. Further, thinner transmission lines may lead to less line impedance change over a given frequency range (e.g., compared to a wider transmission line), while also allowing a smaller chip size because the transmission line is thinner.

In some embodiments, “pre-thinned” components may be provided, where a first substrate is provided at a certain thickness (e.g., by using techniques described herein) such that the performance values (e.g., frequency range, etc.) are known because the thickness of the first substrate is not subsequently changed; a second or cover substrate may be disposed on the first substrate as described herein.

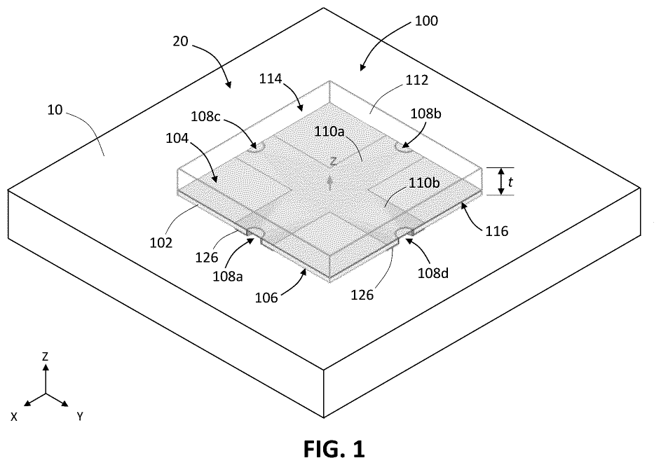

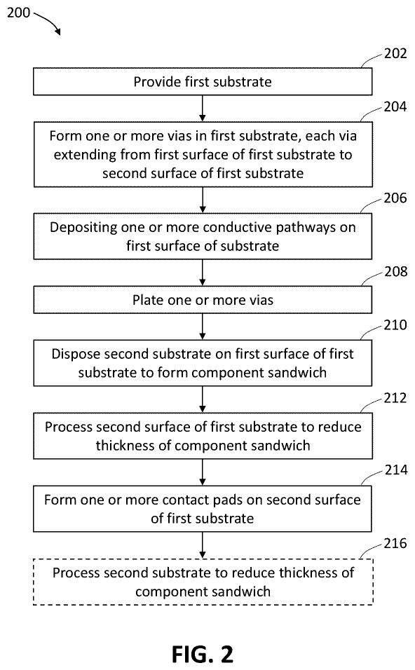

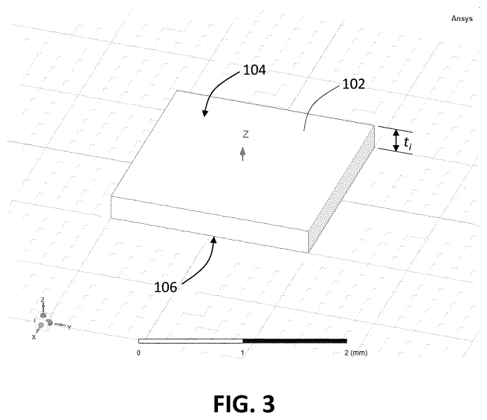

Referring now to the figures, FIG. 1 illustrates a component 100 mounted on a mounting surface 20 of a device 10, such as a printed circuit board (PCB) or the like. In at least some embodiments, the component 100 may be referred to as an ultra-thin sandwich component. FIGS. 3-11 illustrate the formation of the component 100, e.g., according to a method 200 as described with respect to FIG. 2. FIG. 12 illustrates a method 1200 of assembling the component 100 on an electronic device, such as the device 10 shown in FIG. 1.

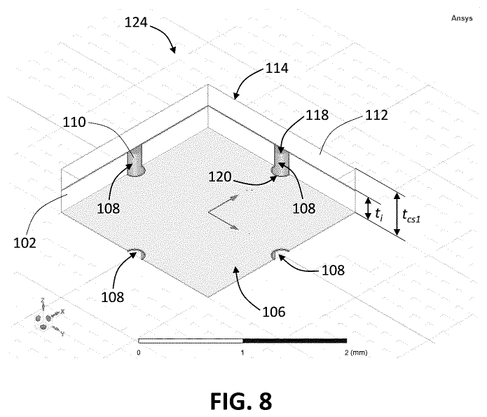

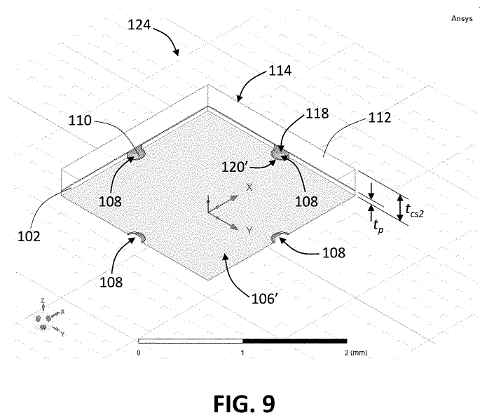

As shown in FIG. 1, the component 100 includes a first substrate 102 having a first surface 104 (FIG. 3) and a processed second surface 106′ opposite the first surface 104. The processed second surface 106′ is positioned against the mounting surface 20. Processing of the first substrate 102 to form the processed second surface 106′ is described in greater detail herein, e.g., with respect to FIGS. 8 and 9. Further, although FIG. 1 illustrates the component 100 mounted on the mounting surface 20 of the device 10, it will be appreciated that, in other embodiments, the component 100 may be embedded within the device 10, etc. such that the component 100 is secured to the device 10 other than by mounting the component 100 on the mounting surface 20. The device 10 may be an electronic device such as a printed circuit board (PCB) or the like.

The exemplary component 100 of FIG. 1 also includes four vias 108 defined in the first substrate 102—a first via 108a, a second via 108b, a third via 108c, and a fourth via 108d. Each via 108 extends from the first surface 104 of the first substrate 102 to the processed second surface 106′ of the first substrate 102.

As shown in FIG. 1, conductive pathways 110 formed on the first surface 104 of the first substrate 102 connect the vias 108. More particularly, a first conductive pathway 110a extends from the first via 108a to the second via 108b and a second conductive pathway 110b extends from the third via 108c to the fourth via 108d. The conductive pathways 110 may be formed from any conductive material suitable for electrical conduction such that the first conductive pathway 110a electrically connects the first via 108a and the second via 108b and the second conductive pathway 110b electrically connects the third via 108c and the fourth via 108d. For example, the conductive pathways 110 may be formed from a metallic material such as copper, nickel, gold, silver, or other metals or alloys or any suitable electrically conductive material.

As an example, each conductive pathway 110 may include one or more conductive layers formed on the first substrate 102, which may be formed from an electrically non-conductive material such as a dielectric material. The conductive layers may include a variety of conductive materials. For example, the conductive layers may include copper, nickel, gold, silver, or other metals or alloys. The conductive layers may be formed using a variety of suitable techniques. Subtractive, semi-additive or fully additive processes may be employed with panel or pattern electroplating of the conductive material followed by print and etch steps to define patterned conductive layers. Photolithography, plating (e.g., electrolytic), sputtering, vacuum deposition, printing, or other techniques may be used to for form the conductive layers. For example, a thin layer (e.g., a foil) of a conductive material may be adhered (e.g., laminated) to a surface of a dielectric layer. The thin layer of conductive material may be selectively etched using a mask and photolithography to produce a desired pattern of the conductive material on the surface of the dielectric material.

Further, in the depicted embodiment, the conductive material forming the conductive pathways 110 extends within each via 108 such that the conductive pathways 110 extend between the first surface 104 and the processed second surface 106′ of the first substrate 102. For instance, each via 108 may be plated with the conductive material such that the conductive material extends within each via 108. One or more contact pads 126 may be disposed on the processed second surface 106′ of the first substrate 102 to help connect the conductive pathways 110 to the device 10, e.g., each contact pad 126 may surround a respective one via 108 at the processed second surface 106′ of the first substrate 102.

As further illustrated in FIG. 1, a second substrate 112 is positioned over the first substrate 102. The second substrate 112 has a first surface 114 and a second surface 116 opposite the first surface 114. The second substrate 112 is positioned over the first substrate 102 such that the second surface 116 of the second substrate 112 is positioned in contact with the first surface 104 of the first substrate 102. The second substrate 112 may be, e.g., a top cover or cover substrate, sandwiching the conductive pathways 110 between the first or bottom substrate 102 and the second or top substrate 112. It will be appreciated that the second substrate 112 is shown as transparent in FIG. 1 (and throughout the figures) for the purposes of illustration only, e.g., to make visible for ease of discussion herein the conductive pathways 110, etc. that are sandwiched between the first substrate 102 and the second substrate 112.

The component has a thickness t of less than about 40 mils (0.004 inches). The second substrate 112 may be configured to be processed to further reduce the thickness t of the component 100. After processing, the first substrate 102 and the second substrate 112 each may have a thickness within a range of about 2 mils to about 30 mils. In some embodiments, the first substrate 102 and the second substrate 112 may have the same thickness. In other embodiments, one of the first substrate 102 or the second substrate 112 may be thicker than the other of the first substrate 102 or the second substrate 112, with the total thickness t of the component 100 being less than about 40 mils. For example, in one embodiment, the thickness of the first substrate 102 may be about 3 mils and the thickness of the second substrate 112 may be about 3 mils such that the thickness t of the component 100 is about 6 mils. As another example, the thickness of the first substrate 102 may be about 3 mils and the thickness of the second substrate 112 may be about 5 mils such that the thickness t of the component 100 is about 8 mils. As yet other examples, the thickness of the first substrate 102 may be about 4 mils and the thickness of the second substrate 112 may be about 3 mils such that the thickness t of the component 100 is about 7 mils; the thickness of the first substrate 102 may be about 5 mils and the thickness of the second substrate 112 may be about 5 mils such that the thickness t of the component 100 is about 10 mils; or the thickness of the first substrate 102 may be about 10 mils and the thickness of the second substrate 112 may be about 10 mils such that the thickness t of the component 100 is about 20 mils. Other substrate thicknesses may be used as well.

In embodiments in which the second substrate 112 is processed after disposal on the first substrate 102 to further reduce the thickness of the component 100, the second substrate 112 may have a thickness within a range of about 5 mils to about 50 mils prior to processing the second substrate to reduce the thickness of the component 100. Similarly, prior to processing as described herein, the first substrate 102 may have a thickness within a range of about 5 mils to about 50 mils.

The component 100 may include one or more dielectric materials, e.g., at least one of the first substrate 102 or the second substrate 112 may include a dielectric material. In some embodiments, the one or more dielectric materials may have a low dielectric constant. The dielectric constant may be less than about 100, in some embodiments less than about 75, in some embodiments less than about 50, in some embodiments less than about 25, in some embodiments less than about 15, and in some embodiments less than about 5. For example, in some embodiments, the dielectric constant may range from about 1.5 and 100, in some embodiments from about 1.5 to about 75, and in some embodiments from about 2 to about 8. The dielectric constant may be determined in accordance with IPC TM-650 2.5.5.3 at an operating temperature of 25° C. and frequency of 1 MHz. The dielectric loss tangent may range from about 0.001 to about 0.04, in some embodiments from about 0.0015 to about 0.0025.

In some embodiments, the one or more dielectric materials may include organic dielectric materials. Example organic dielectric include polyphenyl ether (PPE) based materials, such as LD621 from Polyclad and N6000 series from Park/Nelco Corporation, liquid crystalline polymer (LCP), such as LCP from Rogers Corporation or W. L. Gore & Associates, Inc., hydrocarbon composites, such as 4000 series from Rogers Corporation., and epoxy-based laminates, such as N4000 series from Park/Nelco Corp. For instance, examples include epoxy based N4000-13, bromine-free material laminated to LCP, organic layers with high K material, unfilled high-K organic layers, Rogers 4350, Rogers 4003 material, and other thermoplastic materials such as polyphenylene sulfide resins, polyethylene terephthalate resins, polybutylene terephthalate resins, polyethylene sulfide resins, polyether ketone resins, polytetraflouroethylene resins and graft resins, or similar low dielectric constant, low-loss organic material.

In some embodiments, the one or more dielectric materials may include a ceramic-filled epoxy. For example, the one or more dielectric materials may include an organic compound, such as a polymer (e.g., an epoxy) and may contain particles of a ceramic dielectric material, such as barium titanate, calcium titanate, zinc oxide, alumina with low-fire glass, or other suitable ceramic or glass-bonded materials.

Other materials may be utilized, however, including, N6000, epoxy based N4000-13, bromine-free material laminated to LCP, organic layers with high K material, unfilled high-K organic layers, Rogers 4350, Rogers 4003 material (from the Rogers Corporation), and other thermoplastic materials such as hydrocarbon, Teflon, FR4, epoxy, polyamide, polyimide, and acrylate, polyphenylene sulfide resins, polyethylene terephthalate resins, polybutylene terephthalate resins, polyethylene sulfide resins, polyether ketone resins, polytetraflouroethylene resins, BT resin composites (e.g., Speedboard C), thermosets (e.g., Hitachi MCL-LX-67F), and graft resins, or similar low dielectric constant, low-loss organic material. Dielectric materials such as diamond and cubic boron arsenide may be used as well.

Additionally, non-organic dielectric materials may be used including a ceramic, semi-conductive, or insulating materials, such as, but not limited to barium titanate, calcium titanate, zinc oxide, alumina with low-fire glass, or other suitable ceramic or glass-bonded materials. Alternatively, the dielectric material may be an organic compound such as an epoxy (with or without ceramic mixed in, with or without fiberglass), popular as circuit board materials, or other plastics common as dielectrics. In these cases, the conductor may be a copper foil which is chemically etched to provide the patterns. In still further embodiments, dielectric material may comprise a material having a relatively high dielectric constant (K), such as one of NPO (COG), X7R, X5R X7S, Z5U, Y5V and strontium titanate. In such examples, the dielectric material may have a dielectric constant that is greater than 100, for example within a range from between about 100 to about 4000, in some embodiments from about 1000 to about 3000.

Referring now to FIGS. 2-11, formation of the component 100 will be described in greater detail. As shown at 202 in FIG. 2, a method 200 of forming the component 100 can include providing the first substrate 102. As illustrated in FIG. 3, the first substrate 102 includes a first surface 104 and a second surface 106 opposite the first surface 104 along a height direction Z. The first substrate 102 may have an initial thickness tᵢ from the first surface 104 to the second surface 106 along the height direction Z.

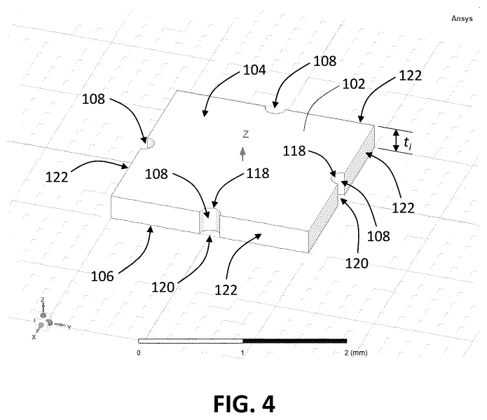

As shown at 204 in FIG. 2, the method 200 may further include forming one or more vias 108 in the first substrate 102. Referring to FIG. 4, each via 108 of the one or more vias 108 may extend from the first surface 104 of the first substrate 102 to the second surface 106 of the first substrate 102. For instance, a first end 118 of a respective one via 108 may be defined at the first surface 104 of the first substrate, and a second end 120 of a respective one via 108 may be defined at the second surface 106 of the first substrate 102. Each via 108 may extend from its first end 118 to its second end 120. One or more of the vias 108 may be formed by drilling or by any other suitable process.

In some embodiments, as shown in FIG. 4, the vias 108 may be formed along the sides 122 of the first substrate 102, but in other embodiments, one or more vias 108 may be defined in other locations of the first substrate 102. For example, one or more vias 108 may be spaced apart from the sides 122 of the first substrate 102 such that a portion of the first substrate 102 extends between a respective via 108 and a side 122 of the first substrate 102.

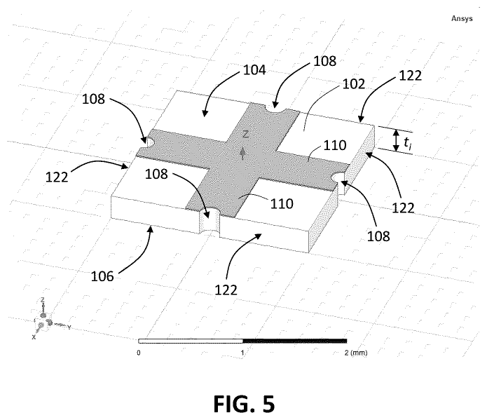

Referring to 206 in FIG. 2, the method 200 may include depositing one or more conductive pathways 110 on the first surface 104 of the first substrate 102. As shown in FIG. 5, each conductive pathway 110 may extend between two or more vias 108. For instance, as described with respective to FIG. 1, a first conductive pathway 110a may extend from a first via 108a to a second via 108b, and a second conductive pathway 110b may extend from a third via 108c to a fourth via 108d. Along the first surface 104, the one or more conductive pathways 110 can extend from the first end 118 of a respective via 108 to the first end 118 of another via 108. The conductive pathway(s) 110 may be formed from any suitable electrically conductive material, as described elsewhere herein.

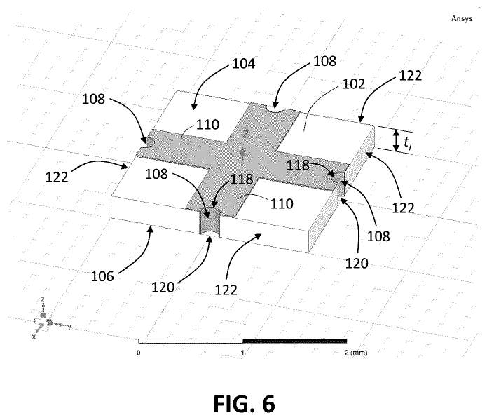

As described with respect to FIG. 1, the conductive pathways 110 can also extend within one or more of the vias 108. For example, as shown at 208 in FIG. 2, the method 200 may include plating one or more of the vias 108 such that a respective conductive pathway 110 extends to the second end 120 of a respective plated via 108 as illustrated in FIG. 6. That is, a respective conductive pathway 110 may extend within a via 108 (e.g., through plating the via 108) such that electrical conduction through the conductive pathway 110 extends to the second surface 106 of the first substrate 102 (as also illustrated in FIG. 8, which provides a perspective view of a component sandwich 124 from the second surface 106).

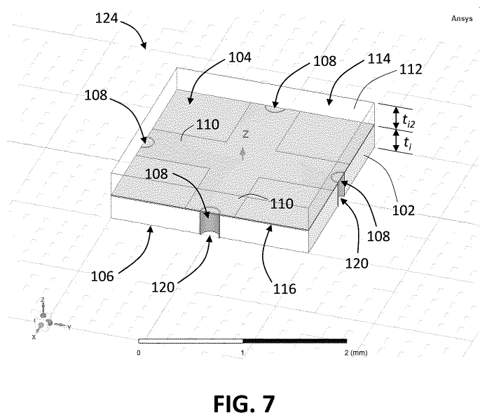

Referring to 210 in FIG. 2, the method can also include disposing a second substrate 112 on the first surface 104 of the first substrate 102 to form a component sandwich 124. As shown in FIG. 7, where the second substrate 112 is illustrated as transparent for ease of explanation of the relative position of various portions of the component 100, the second substrate 112 has a first surface 114 and a second surface 116 that is opposite the first surface 114 along the height direction Z. The second substrate 112 has an initial thickness tᵢ₂ from the first surface 114 to the second surface 116 along the height direction Z. The second substrate 112 is positioned with respect to the first substrate 102 such that the second surface 116 of the second substrate 112 covers the first surface 104 of the first substrate 102.

As shown at 212 in FIG. 2, the method may further include processing the second surface 106 of the first substrate 102 to reduce a thickness of the component sandwich 124 and define a processed second surface 106′ of the first substrate 102. Referring to FIGS. 8 and 9, prior to processing the second surface 106 of the first substrate 102, the component sandwich 124 has a first thickness t_{cs1}, and the first substrate 102 has the initial thickness tᵢ as described above. After processing the first substrate 102, the component sandwich 124 has a second thickness t_{cs2}, and the first substrate 102 has a processed thickness tₚ. Processing the first substrate 102 to reduce its thickness can include grinding the first substrate 102 or otherwise processing the first substrate 102 to reduce its thickness. After processing the first substrate 102, the conductive material within the one or more vias 108 having the conductive material extends to the processed second surface 106′ of the first substrate 102 such that the conductive pathways 110 extend to and are exposed along the processed second surface 106′ of the first substrate 102, e.g., the conductive pathways 110 extend to a processed second end 120′ of a respective via 108.

The second substrate 112 can reinforce the first substrate 102 such that the first substrate 102 may be processed or thinned to a relatively extreme level or may be “ultra-thinned” without warping or cracking the first substrate 102 and/or the component sandwich 124. For example, the first substrate 102 may be processed to about one half (about 50%) or less of its initial thickness tᵢ, such as to about one third (about 33%), to about one fourth (about 25%), about one fifth (about 20%), to about one sixth (about 17%), to about one eighth (about 12.5%) or less of the initial thickness tᵢ of the first substrate 102.

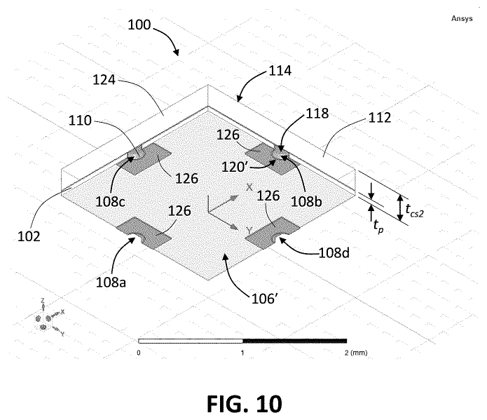

Referring to 214 in FIG. 2, the method 200 also may include forming one or more contact pads 126 on the processed second surface 106′ of the first substrate 102. As shown in FIG. 10, in at least some embodiments, each contact pad 126 of the one or more contact pads 126 surrounds a respective one via 108 at the processed second surface 106′ of the first substrate 102 such that each contact pad 126 is in electrical contact with a respective via 108 and, thereby, a respective conductive pathway 110. For instance, as described herein, the respective via 108 may be plated or otherwise lined or filled with a conductive material to electrically connect the respective conductive pathway 110 with a respective contact pad 126. In the embodiment of FIG. 10, the one or more contact pads 126 includes a first contact pad 126 surrounding and in electrical contact with a first via 108a, a second contact pad 126 surrounding and in electrical contact with a second via 108b, a third contact pad 126 surrounding and in electrical contact with a third via 108c, and a fourth contact pad 126 surrounding and in electrical contact with a fourth via 108d. It will be appreciated that the contact pads 126 may increase the contact area of the conductive pathways 110 on the processed second surface 106′ of the first substrate 102, e.g., to increase contact between the conductive pathways 110 and a device 10 to which the component 100 is secured.

As described with respect to FIG. 1, the component 100 can be secured to a device 10, e.g., by mounting the component 100 on a mounting surface 20 defined by the device 10, by embedding the component 100 within the device 10, or otherwise securing the component 100 to the device 10. Before or after securing the component 100 to the device 10, the second substrate 112 may be thinned to further reduce the thickness of the component 100. For example, as shown at 216 in FIG. 2, the method 200 optionally may include processing the first surface 114 of the second substrate 112 to reduce the thickness of the component sandwich 124.

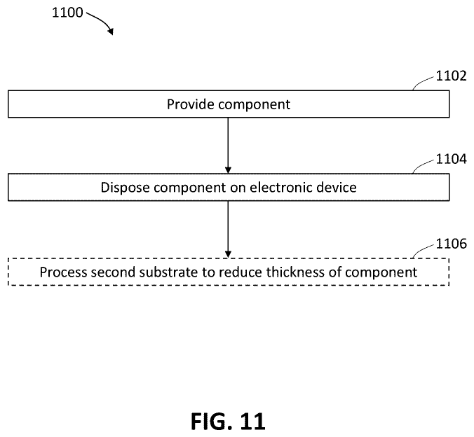

In other embodiments, the second substrate 112 may be processed after securing the component 100 to the device 10. For instance, referring now to FIG. 11, a method 1100 of assembling a component on an electronic device may include, as shown at 1102, providing the component, such as the component 100 as described herein. At 1104, the method 1100 further may include securing the component to the electronic device, which may be a device such as device 10 described herein. As described above, securing the component to the electronic device may include mounting the component on a mounting surface 20 of the device 10, partially or fully embedding the component in the device 10, or otherwise securing the component to the electronic device. For example, partially embedding the component 100 within the device 10 may dispose a portion of the component 100 within the device 10 while the remainder of the component 100 protrudes from or is external to the device 10; fully embedding the component 100 within the device 10 may dispose the entirety of the component 100 within the device 10 (e.g., such that, at most, one or more surfaces of the component 100 are co-planar with one or more surfaces of the device 10 while the remainder of the component 100 is surrounded by the device 10). Securing the component to the electronic device may include, e.g., soldering the component to the electronic device, and/or using other mechanical or chemical attachment mechanisms.

As shown at 1106 in FIG. 11, the method 1100 also may include, after securing the component to the electronic device, processing the second substrate 112 to reduce a thickness of the second substrate 112 and, thereby, the component. For instance, after securing the component 100 to the mounting surface 20 of the device 10, the first surface 114 of the second substrate 112 may be processed by grinding or the like to modify the height or thickness of the component 100. Thus, the height or thickness of the component 100 may be modified in circuit to achieve a desired or needed dimension. A final thickness of the component 100 may be within a range of about 2 mils to about 40 mils, such as within a range of about 3 mils to about 20 mils or within a range of about 4 mils to about 12 mils.

### Applications

The various embodiments of reduced height components disclosed herein may have a variety of applications. For example, a reduced height sandwich component as described herein may be a filter for high frequency applications, such as filtering of high frequency signals in high frequency radio signal communication, e.g., as may be used for increased data transmission speed for wireless connectivity such as within 5G spectrum frequencies or higher. Of course, the reduced height components described herein may be other types of components than filters and may be used in other applications than as described herein.

These and other modifications and variations of the present invention may be practiced by those of ordinary skill in the art, without departing from the scope of the present invention. In addition, it should be understood that aspects of the various embodiments may be interchanged both in whole or in part. Further, those of ordinary skill in the art will appreciate that the foregoing description is by way of example only and is not intended to limit the invention so further described in such appended claims.

What is claimed is:

1. A method of forming a component, the method comprising:
providing a first substrate having a first surface, a second surface opposite the first surface along a height direction, and an initial thickness from the first surface to the second surface along the height direction;
forming one or more vias in the first substrate, each via of the one or more vias extending from the first surface of the first substrate to the second surface of the first substrate;
depositing one or more conductive pathways on the first surface of the first substrate;
plating the one or more vias;
disposing a second substrate on the first surface of the first substrate to form a component sandwich;
processing the second surface of the first substrate to reduce a thickness of the component sandwich and define a processed second surface of the first substrate; and
forming one or more contact pads on the processed second surface of the first substrate.

2. The method of claim 1, wherein the component sandwich has a thickness less than about 40 mils.

3. The method of claim 2, wherein then thickness of the component sandwich is less than about 20 mils.

4. The method of claim 1, wherein forming one or more vias in the first substrate comprises drilling each via of the one or more vias.

5. The method of claim 1, wherein processing the second surface of the first substrate comprises grinding the second surface of the first substrate.

6. The method of claim 1, wherein forming one or more vias includes forming a first via extending from a first end at the first surface of the first substrate to a second end at the second surface of the first substrate and a second via extending from a first end at the first surface of the first substrate to a second end at the second surface of the first substrate.

7. The method of claim 6, wherein depositing one or more conductive pathways includes depositing a first conductive pathway extending from the first end of the first via to the first end of the second via.

8. The method of claim 7, wherein each via of the one or more vias and the plating of each via of the one or more vias is exposed along the processed second surface, and wherein forming one or more contact pads includes forming a first contact pad in electrical contact with the first via and a second contact pad in electrical contact with the second via.

9. The method of claim 8, wherein:
forming one or more vias includes forming a third via extending from a first end at the first surface of the first substrate to a second end at the second surface of the first substrate and a fourth via extending from a first end at the first surface of the first substrate to a second end at the second surface of the first substrate;
depositing one or more conductive pathways includes depositing a second conductive pathway extending from the first end of the third via to the first end of the fourth via; and
forming one or more contact pads includes forming a third contact pad in electrical contact with the third via and a fourth contact pad in electrical contact with the fourth via.

10. The method of claim 1, wherein the component is configured to be disposed on a mounting surface of an electronic device.

11. The method of claim 1, wherein the component is configured to be embedded within an electronic device.

12. The method of claim 1, wherein the second substrate is configured to be processed to further reduce a thickness of the component sandwich.

13. The method of claim 1, wherein the second substrate is configured to be ground to further reduce a thickness of the component sandwich.

14. A method of forming a component, the method comprising:
providing a first substrate having a first surface, a second surface opposite the first surface along a height direction, and an initial thickness from the first surface to the second surface along the height direction;
depositing one or more conductive pathways on the first surface of the first substrate, at least one conductive pathway of the one or more conductive pathways extending through the first substrate from the first surface to the second surface;
disposing a second substrate on the first substrate, the second substrate having a first surface, a second surface opposite the first surface along a height direction, and an initial thickness from the first surface to the second surface along the height direction, the second surface of the second substrate positioned against the first surface of the first substrate; and
processing the second surface of the first substrate to reduce the initial thickness of the first substrate to a processed thickness.

15. The method of claim 14, further comprising, prior to depositing one or more conductive pathways:
forming one or more vias in the first substrate, each via extending through the first substrate from the first surface of the first substrate to the second surface of the first substrate.

16. The method of claim 15, wherein depositing one or more conductive pathways comprises plating at least one of the one or more vias.

17. The method of claim 14, further comprising, after processing the second surface of the first substrate:
forming one or more contact pads on the second surface of the first substrate, each contact pad in contact with at least one conductive pathway at the second surface of the first substrate.

18. The method of claim 14, wherein processing the second surface of the first substrate comprises grinding the second surface of the first substrate to define a processed second surface.

19. A component, comprising:
a first substrate having a first surface and a second surface opposite the first surface;
one or more vias defined in the first substrate, each via of the one or more vias extending from the first surface of the first substrate to the second surface of the first substrate, the one or more vias including a first via and a second via, the one or more vias including an electrically conductive material;
one or more conductive pathways on the first surface of the first substrate, the one or more conductive pathways including a first conductive pathway extending from the first via to the second via;
one or more contact pads formed on the second surface of the first substrate, each contact pad of the one or more contact pads surrounding a respective one via of the one or more vias at the second surface such that each contact pad is in electrical contact with a respective one via; and
a second substrate having a first surface and a second surface opposite the first surface, the second substrate positioned over the first substrate such that the second surface of the second substrate is positioned in contact with the first surface of the first substrate,
wherein the component has a thickness of less than about 40 mils.

20. The component of claim 19, wherein the component has a thickness of less than about 20 mils.

21. The component of claim 19, wherein each via of the one or more vias is plated with a conductive material to electrically connect the one or more conductive pathways with the one or more contact pads.

22. The component of claim 19, wherein the one or more contact pads includes a first contact pad surrounding and in electrical contact with the first via and a second contact pad surrounding and in electrical contact with the second via.

23. The component of claim 19, wherein the one or more vias includes a third via and a fourth via, and wherein the one or more conductive pathways includes a second conductive pathway extending from the third via to the fourth via.

24. The component of claim 23, wherein the one or more contact pads includes a third contact pad surrounding and in electrical contact with the third via and a fourth contact pad surrounding and in electrical contact with the fourth via.

25. The component of claim 19, wherein the second substrate is configured to be processed to reduce the thickness of the component.

26. The component of claim 25, wherein the first substrate has a thickness within a range of about 2 mils to about 20 mils, and wherein the second substrate has a thickness within a range of about 5 mils to about 40 mils prior to processing the second substrate to reduce the thickness of the component.

27. The component of claim 25, wherein the second substrate is configured to be ground to reduce the thickness of the component.

28. A method of assembling a component on an electronic device, the method comprising:
providing the component, the component comprising:
a first substrate having a first surface and a second surface opposite the first surface,
one or more vias defined in the first substrate, each via of the one or more vias extending from the first surface of the first substrate to the second surface of the first substrate, the one or more vias including a first via and a second via, the one or more vias plated with an electrically conductive material,
one or more conductive pathways on the first surface of the first substrate, the one or more conductive pathways including a first conductive pathway extending from the first via to the second via,
one or more contact pads formed on the second surface of the first substrate, each contact pad of the one or more contact pads surrounding a respective one via of the one or more vias at the second surface such that each contact pad is in electrical contact with a respective one via, and
a second substrate having a first surface and a second surface opposite the first surface, the second substrate positioned over the first substrate such that the second surface of the second substrate is positioned in contact with the first surface of the first substrate,
wherein the component has a thickness of less than about 40 mils;
securing the component to the electronic device; and
processing the second substrate to reduce a thickness of the second substrate.
